(19) United States
(12) Patent Application Publication
(10) Pub. No.: US 2014/0045411 A1
(43) Pub. Date: Feb. 13, 2014

(54) METHODS OF AND APPARATUS FOR PRODUCING WAFERS

(71) Applicants: Yevsey SENDERZON, San Jose, CA (US); Michael LYU, San Jose, CA (US)

(72) Inventors: Yevsey SENDERZON, San Jose, CA (US); Michael LYU, San Jose, CA (US)

(21) Appl. No.: 13/571,809

(22) Filed: Aug. 10, 2012

(51) Int. Cl. B24B 41/06; H01L 21/304; H01L 21/683

(52) U.S. Cl. 451/41; 451/28; 451/364

(57) ABSTRACT

An aspect of the present invention pertains to a method of fabricating wafers. One embodiment comprises a method of processing a substrate having defects into a wafer. The method comprises grinding the substrate to flatness while supporting the substrate in a grinding apparatus so that there is minimum or substantially zero stress on the substrate. Another aspect of the present invention comprises a substrate holder for holding a substrate as part of grinding processes to produce a flat surface on the substrate.

### BACKGROUND

One or more embodiments of the present invention pertain to fabrication of wafers of hard materials for use in the fabrication of electronic devices, optoelectronic devices, optical devices, transistors, and/or integrated circuits; more specifically, one or more embodiments of the present invention relate to materials and processes to grind hard substrates to make low stress wafers or wafers with a controlled amount of stress.

The present inventors have made one or more discoveries that may be pertinent to using grinding processes to fabricate wafers of hard materials from hard substrates. The one or more discoveries may have the potential to provide one or more methods and apparatuses for economical fabrication of high-quality wafers made from hard materials.

### SUMMARY

One aspect of the present invention pertains to a method of fabricating wafers. One embodiment of the present invention comprises a method of processing a substrate having defects such as, but not limited to, bowing, warpage, and/or thickness nonuniformity into a wafer such as a flat wafer. The substrate has a first side and a second side. The method comprises grinding the second side of the substrate to flatness while supporting the substrate in a grinding apparatus so that there is minimum or substantially zero stress on the substrate. The method may further comprise grinding the first side of the substrate to flatness while supporting the substrate in a grinding apparatus so that there is minimum or substantially zero stress on the substrate.

Another aspect of the present invention comprises a substrate holder for holding a substrate as part of grinding processes to produce a flat surface on the substrate.

It is to be understood that the invention is not limited in its application to the details of construction and to the arrangements of the components set forth in the following description. The invention is capable of other embodiments and of being practiced and carried out in various ways. In addition, it is to be understood that the phraseology and terminology employed herein are for the purpose of description and should not be regarded as limiting.

### BRIEF DESCRIPTION OF THE DRAWINGS

FIG. 1 is a side view of an example of a substrate.

FIG. 2 is a side view of a wafer fabricated according to an embodiment of the present invention.

FIG. 3 is a side view of a wafer holder according to an embodiment of the present invention.

FIG. 4 is a side view of an embodiment of the present invention.

FIG. 5 is a side view of an embodiment of the present invention.

FIG. 6 is a side view of an embodiment of the present invention.

FIG. 7 is a side view of an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help to improve understanding embodiments of the present invention.

### DESCRIPTION

In the following description of the figures, identical reference numerals have been used when designating substantially identical elements or processes that are common to the figures.

For the following defined terms, these definitions shall be applied, unless a different definition is given in the claims or elsewhere in this specification. All numeric values are herein defined as being modified by the term “about,” whether or not explicitly indicated. The term “about” generally refers to a range of numbers that a person of ordinary skill in the art would consider equivalent to the stated value to produce substantially the same properties, function, result, etc. A numerical range indicated by a low value and a high value is defined to include all numbers subsumed within the numerical range and all subranges subsumed within the numerical range. As an example, the range 10 to 15 includes, but is not limited to, 10, 10.1, 10.47, 11, 11.75 to 12.2, 12.5, 13 to 13.8, 14, 14.025, and 15.

The order of execution or performance of the operations or the processes in embodiments of the invention illustrated and described herein is not essential, unless otherwise specified. That is, the operations or the processes may be performed in any order, unless otherwise specified, and embodiments of the invention may include additional or fewer operations or processes than those disclosed herein. For example, it is contemplated that executing or performing a particular operation or process before, contemporaneously with, or after another operation or process is within the scope of aspects of the invention

The term “horizontal” as used herein is defined as a plane parallel to the plane or surface of the substrate or surface of the wafer, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means there is direct contact among elements.

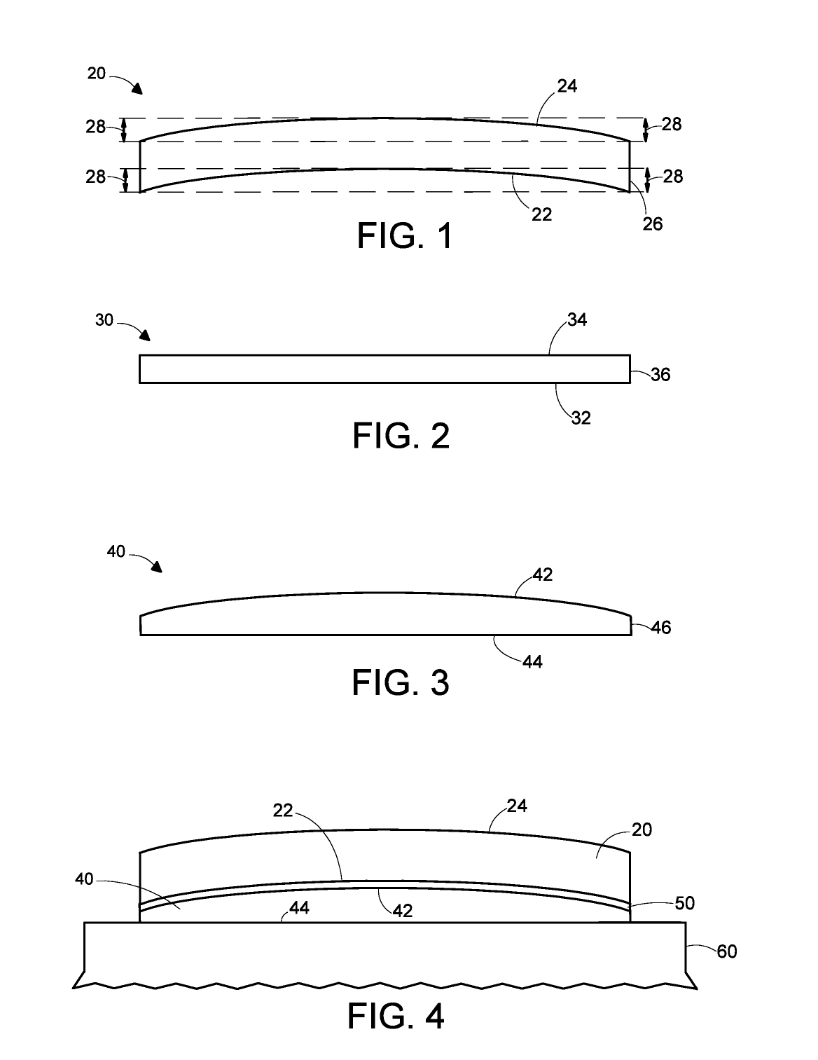

For the present disclosure, the term “substrate” refers to a section of material used for forming a “wafer.” The substrate is a solid at ambient conditions and possesses a substantially rigid physical structure. Although the substrate is substantially rigid, it is susceptible to stresses such as, but not limited to, “flexural stress” which can be caused by bending or deformation forces and “torsional stress” which can be caused by shearing forces. FIG. 1 shows a side view of an example of a substrate 20, which has a first side 22, a second side 24, and a side edge 26. Second side 24 is opposite first side 22. Side edge 26 extends between first side 22 and second side 24.

Substrates used with one or more embodiments of the present invention have defects that may contribute to making them undesirable for use as wafers. Typically, the substrates may be bowed, the substrates may be warped, the substrates may be non-uniform in thickness, the substrates may have surface protrusions such as bumps, the substrates may have recesses such as indentations or holes, and the surface may have a combination of such defects.

Substrate 20 is shown in FIG. 1 to be bowed and/or warped. The amount of bowing or warpage is illustrated by surface displacement 28 between the outer edge of first side 22 and the center of first side 22. The amount of bowing or warpage is also illustrated by surface displacement 28 between the outer edge of second side 24 and the center of second side 24. It is to be noted that substrate 20 is merely exemplary. Substrate 20 could have an amount of bowing and/or warpage for first side 22 that is different from the amount of bowing and/or warpage for second side 24; such a result can be caused by factors such as, but not limited to, nonuniformity in the thickness of substrate 20. Optionally, substrate 20 may also have bumps, recesses, and/or other surface defects.

For the present disclosure, the term “wafer” refers to a workpiece such as that for forming and/or supporting devices such as integrated circuits, electronic devices, optical devices, optoelectronic devices, and for other uses. FIG. 2 shows a side view of an example of a wafer 30 which has a first side 32, a second side 34, and a side edge 36. Second side 34 is opposite first side 32. Side edge 36 extends between first side 32 and the second side 34. Generally, side edge 36 dimensions are smaller than the dimensions of first side 32 and the dimensions of second side 34 so that wafer 30 has a thin profile.

Wafers produced according to one or more embodiments of the present invention meet predetermined specifications for properties such as bowing, warpage, stress, and/or thickness nonuniformity. Typically, wafers produced according to one or more embodiments of the present invention have less bowing, less warpage, less stress, and/or less thickness nonuniformity than was present in the substrate from which the wafer was fabricated.

One or more embodiments of the present invention pertain to methods and/or apparatus for using grinding processes to fabricate wafers from substrates. According to one or more embodiments of the present invention, the fabricated wafers characteristically have low stress as exhibited by flatness of the wafers, low bowing, and/or low warpage. According to one or more embodiments of the present invention, the thickness of the wafers is substantially uniform and/or meets predetermined specifications. According to one or more embodiments of the present invention, wafers meeting predetermined specifications are produced faster and/or more economically than is possible using other methods of fabrication.

Embodiments of the present invention will be discussed below primarily in the context of fabricating wafers such as aluminum nitride wafers used for fabricating electronic devices, optoelectronic devices, and/or optical devices for applications such as, but not limited to, light emitting diodes, high brightness light emitting diodes, transistors, and high-power transistors; however, it is to be understood that embodiments in accordance with the present invention may be used for other types of semiconductor devices, wafers other than aluminum nitride, and other types of devices.

One aspect of the present invention pertains to a method of fabricating wafers. One embodiment of the present invention comprises a method of processing a substrate having defects such as, but not limited to, bowing, warpage, and/or thickness nonuniformity into a wafer such as a flat wafer. The substrate has a first side and a second side. The method comprises grinding the second side of the substrate to flatness while supporting the substrate in a grinding apparatus so that there is minimum or substantially zero stress on the substrate which can cause residual stress in the wafer such as, but not limited to, flexural stress. The method further comprises grinding the first side of the substrate to flatness while supporting the substrate in a grinding apparatus so that there is minimum or substantially zero stress such as flexural stress on the substrate.

A variety of grinding apparatuses can be used for embodiments of the present invention. Some examples of commercially available grinding equipment for embodiments of the present invention include, but are not limited to, Okamoto GNX-200 and Okamoto VG-502 by Okamoto Corporation of Buffalo Grove, Ill., USA; and Strasbaugh 7AF by Strasbaugh Corporation of San Luis Obispo, Calif., USA.

According to one embodiment of the present invention, the method comprises providing the substrate as a hard material. According to one or more embodiments of the present invention, the substrate comprises aluminum nitride. According to one or more other embodiments of the present invention, the substrate comprises aluminum carbide, aluminum oxide, boron nitride, cerium oxide, garnet, magnesium oxide, silicon carbide, silicon nitride, zirconium oxide, or combinations thereof. Garnets for embodiments of the present invention include garnets such as, but not limited to, gadolinium gallium garnet and/or other types of garnets. Optionally, the aluminum oxide substrates according to one or more embodiments of the present invention comprise sapphire.

According to one embodiment of the present invention, the supporting the substrate in a grinding apparatus so that there is minimum or substantially zero flexural stress on the substrate for the grinding the second side of the substrate is accomplished by providing a substantially rigid substrate holder having a holding surface. The holding surface has a surface contour opposite the surface contour of the first side of the substrate so as to provide a substantially conformal fit to the first side of the substrate. In general, this means that for areas on the first side of the substrate that are concave, there are areas on the holding surface of the wafer holder that are convex so that the concave areas and the convex areas substantially fit together. For areas on the first side of the substrate that form a bump there is a corresponding area on the holding surface of the wafer holder that is recessed or indented so that the bump and the recessed area substantially fit together. For other types of features on the first side of the substrate, there are corresponding negative features formed on the holding surface so that the first side of the substrate and the holding surface of the wafer holder substantially fit together.

The method further includes, prior to grinding the second side of the substrate, a process of releasably binding the first side of the substrate to the holding surface of the substrate holder. The process of releasably binding the first side of the substrate to the holding surface of the substrate holder may include processes such as, but not limited to, placing the first side of the substrate together with the holding surface of the substrate holder. According to another embodiment of the present invention, the process of releasably binding the first side of the substrate to the holding surface of the substrate holder may include processes such as, but not limited to, placing the first side of the substrate together with the holding surface of the substrate holder with an amount of a binder dispersed between the first side of the substrate and the holding surface of the substrate holder.

According to another embodiment of the present invention, the supporting the substrate in a grinding apparatus so that there is minimum or substantially zero flexural stress on the substrate for the grinding the second side is accomplished by providing a substantially rigid substrate holder having a holding surface. The holding surface has a surface contour opposite the surface contour of the first side of the substrate so as to provide a substantially conformal fit to the first side of the substrate. The method further comprises releasably binding the first side of the substrate to the holding surface of the substrate holder while the second side of the substrate is ground to flatness. More specifically, the bottom surface of the substrate holder is supported by and/or coupled to a workpiece support of the grinding apparatus. The support may be a chuck such as an electrostatic chuck, a mechanical chuck, and/or a vacuum chuck. According to one embodiment, the bottom surface of the substrate holder is flat so that it makes a flat contact with typical chucking surfaces which, typically, are also flat.

According to one or more embodiments of the present invention, the supporting the substrate in a grinding apparatus so that there is minimum or substantially zero flexural stress on the substrate for the grinding the first side of the substrate is accomplished by providing a grinding machine support such as, but not limited to, a mechanical chuck, a vacuum chuck, or an electrostatic chuck, and holding the second side of the substrate that has been ground to flatness on the grinding machine support such as a mechanical chuck, a vacuum chuck and/or an electrostatic chuck. More specifically, the second side of the substrate is flat from being ground and the second side is held on a flat holding surface of a grinding machine support such as a vacuum chuck, electrostatic chuck, mechanical chuck, etc.

Reference is now made to FIGS. 1, 2, 3, 4, 5, 6, and 7 for illustration of a method of making a wafer according to one or more embodiments of the present invention. The method comprises providing a substrate 20 having a first side 22 and a second side 24 as shown in FIG. 1. First side 22 of substrate 20 has one or more defects such as, but not limited to, bowing, thickness nonuniformity, and/or warpage. FIG. 1 shows substrate 20 having first side 22 bowed into a concave shape. The method comprises providing a substantially rigid substrate holder 40, such as that shown in FIG. 3, having a holding surface 42. Holding surface 42 has a surface contour that is an inverse of the surface contour of first side 22 of substrate 20 so as to provide a substantially conformal fit to first side 22 of substrate 20. For substrate 20 shown in FIG. 1 and substrate holder 40 shown in FIG. 3, first side 22 of substrate 20 is concave and holding surface 42 of substrate holder 40 has been made convex so that the concave first side 22 of substrate 20 forms a substantially conformal fit to convex holding surface 42 of substrate holder 40. Optionally, first side of the substrate may have a shape other than concave and/or may have other defects; for such substrate, the holding surface of the substrate holder would be made with an appropriate opposite surface contour so that the first surface and the holding surface form a substantially conformal fit when placed together.

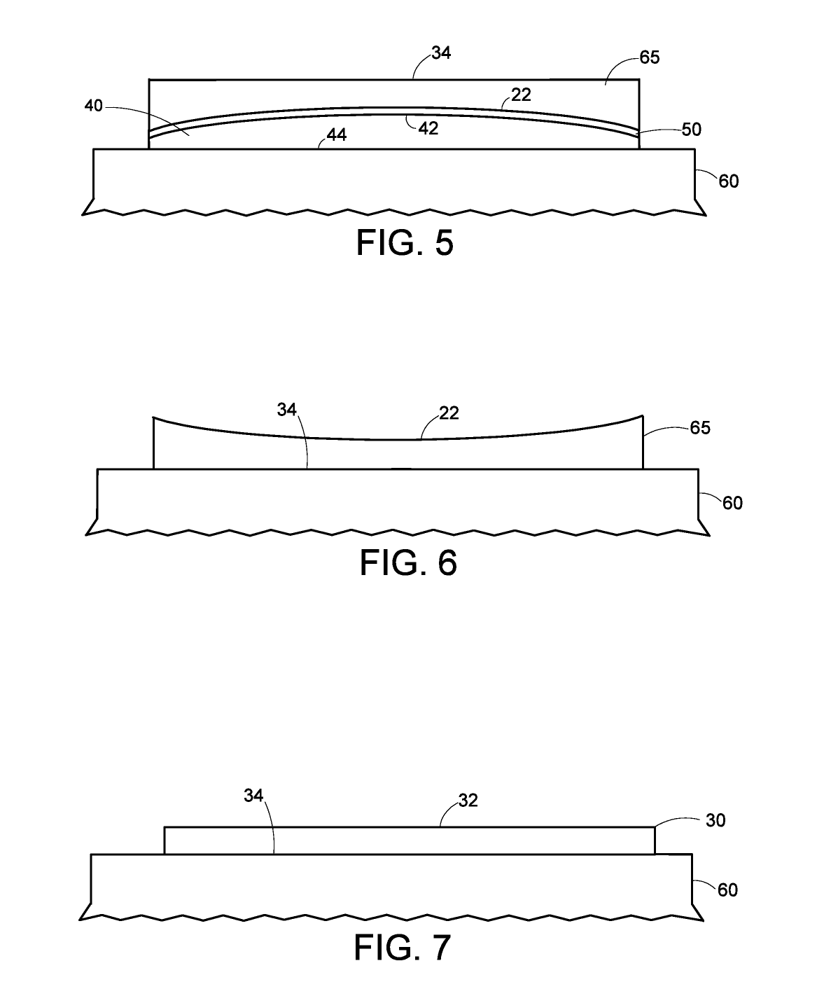

According to one embodiment, the method further comprises providing a binder 50 and releasably binding first side 22 of substrate 20 to holding surface 42 of substrate holder 40 using binder 50 as shown (side view) in FIG. 4 where binder 50 is disposed as a layer between first side 22 of substrate 20 and holding surface 42 of substrate holder 40. FIG. 4 shows bottom surface 44 of substrate holder 40 disposed on grinding machine support 60 so that second side 24 of substrate 20 is positioned to be ground. The method also comprises grinding second side 24 of substrate 20 to produce a substantially flat surface that will be second side 34 of wafer 30 while substrate 20 is bound to substrate holder 40 which is supported in the grinding machine by grinding machine support 60, see FIG. 5. FIG. 5 shows a partially converted substrate 65 that results from grinding second side 24 of substrate 20 to flatness so as to form second side 34.

According to one embodiment of the present invention, the method further comprises grinding first side 22 of substrate 20, which is also first side 22 of partially processed substrate 65 to produce a substantially flat surface to produce wafer 30. FIG. 6 illustrates an option for this process in which partially processed substrate 65 is supported on grinding machine support 60. More specifically, second side 34 of partially processed substrate 65, ground to flatness earlier in the method, is placed on and held by grinding machine support 60 so that first side 22 of partially processed substrate 65 is presented so as to be ground to form first side 32 of wafer 30. The flat surface of second side 34 is supported by the flat surface of grinding machine support 60 which prevents the addition of stress, such as flexural stress, to partially processed substrate 65 by grinding machine support 60 and/or by the grinding process. FIG. 7 shows wafer 30, which results from grinding first side 22 to flatness so as to form first side 32 of wafer 30, shown still on grinding machine support 60.

According to one embodiment of the present invention, the grinding processes produce wafers wherein the bowing is less than or equal to 10 micrometers, warpage is less than or equal 10 micrometers, and/or total thickness variation less than or equal to 1 micrometer.

According to one embodiment of the present invention, the process of providing the substrate comprises providing a substrate that is a hard material such as a material having hardness from 6 up to 9.5 on the Mohs scale. According to one embodiment of the present invention, the substrate is aluminum nitride. According to one or more other embodiments of the present invention, the substrate comprises aluminum carbide, aluminum oxide, boron nitride, cerium oxide, garnet, magnesium oxide, silicon carbide, silicon nitride, zirconium oxide, or combinations thereof. Garnets for embodiments of the present invention include garnets such as, but not limited to, gadolinium gallium garnet and/or other types of garnets. Optionally, the aluminum oxide substrates according to one or more embodiments of the present invention comprise sapphire.

According to one or more embodiments of the present invention, the process of releasably binding first side 22 of substrate 20 to holding surface 42 of substrate holder 40 is accomplished using a binder 50 that is an adhesive. Optionally, binder 50 may comprise materials such as nonpermanent adhesive, polymer resin, and/or removable glue. According to one embodiment of the present invention, binder 50 comprises a wax such as beeswax and/or paraffin wax.

According to one or more embodiments of the present invention, the method is performed having the hardness of substrate 20 greater than or equal to the hardness of substrate holder 40. According to one embodiment of the present invention, the method includes using a substrate holder that is silicon and the substrate is a material of equal or greater hardness. According to one embodiment of the present invention, the method includes using a substrate holder that is silicon and the substrate is aluminum nitride.

According to one or more embodiments of the present invention, the method further comprises polishing the second side of the wafer after the grinding processes. According to one or more embodiments of the present invention, the method further comprises polishing the first side of the wafer after the grinding processes. The polishing processes are performed so as to produce smoother first and/or second sides of the wafer. The polishing can be accomplished using processes such as, but not limited to, diamond polishing, chemical mechanical polishing, or other processes.

Another embodiment of the present invention pertains to a method of making a wafer having a selected amount of stress, such as a controlled and/or predetermined amount of stress. The method comprises providing a substrate having a first side and a second side, and providing a substantially rigid substrate holder having a holding surface. The holding surface has a surface contour that has a predetermined deviation from an inverse of the surface contour of the first side of the substrate so as to provide a partially conformal fit such as an imperfect fit to the first side of the substrate. The method comprises releasably binding the first side of the substrate to the holding surface of the substrate holder and grinding the second side to produce a substantially flat surface while the substrate is bound to the substrate holder. The partially conformal fit means that the attachment of the substrate to the substrate holder with the application of pressure to the substrate such as from a grinding process causes a predetermined amount of stress such as flexural stress or other deformation stress on the substrate during the grinding process. After completion of the grinding of the second side, the wafer fabricated from the substrate retains a residual amount of stress. The amount of residual stress is determined by factors such as the amount of deviation from a conformal fit between the substrate holder and the substrate. The method may further comprise separating the substrate from the substrate holder and grinding the first side of the substrate.

According to one embodiment of the present invention, the grinding processes produce wafers wherein the bowing is a selected amount in the range 0 to 10 micrometers, warpage is a selected amount in the range 0 to 10 micrometers, and/or total thickness variation less than or equal to 1 micrometer.

According to one embodiment of the present invention, the process of providing the substrate comprises providing a substrate that is a hard material such as a material having hardness from 6 up to 9.5 on the Mohs scale. According to one embodiment of the present invention, the substrate is aluminum nitride. According to one or more other embodiments of the present invention, the substrate comprises aluminum carbide, aluminum oxide, boron nitride, cerium oxide, garnet, magnesium oxide, silicon carbide, silicon nitride, zirconium oxide, or combinations thereof. Garnets for embodiments of the present invention include garnets such as, but not limited to, gadolinium gallium garnet and/or other types of garnets. Optionally, the aluminum oxide substrates according to one or more embodiments of the present invention comprise sapphire.

According to one or more embodiments of the present invention, the process of releasably binding the first side of the substrate to the holding surface of the substrate holder is accomplished using a binder that is an adhesive. Optionally, the binder may comprise materials such as nonpermanent adhesive, polymer resin, and/or removable glue. According to one embodiment of the present invention, binder comprises a wax such as beeswax and/or paraffin wax.

According to one or more embodiments of the present invention, the method is performed having the hardness of the substrate greater than or equal to the hardness of the substrate holder. According to one embodiment of the present invention, the method includes using a substrate holder that is silicon and the substrate is a material of equal or greater hardness. According to one embodiment of the present invention, the method includes using a substrate holder that is silicon and the substrate is aluminum nitride.

Another aspect of the present invention comprises a substrate holder for holding a substrate as part of grinding processes to produce a flat surface on the substrate. The substrate has a defective surface characterized by defects such as, but not limited to, being bowed, warped, and/or not uniform in thickness.

FIG. 1 shows an exemplary substrate 20 having a first side 22 and a second side 24. First side 22 of substrate 20 has one or more defects such as, but not limited to, bowing, thickness nonuniformity, and/or warpage. FIG. 1 shows substrate 20 having first side 22 bowed into a concave shape.

FIG. 3 shows an exemplary substrate holder 40. Substrate holder 40 is configured to hold the defective surface of substrate 20 during grinding of the opposite side of the substrate to flatness. Substrate holder 40 comprises a substantially rigid body having a holding surface 42. Holding surface 42 has a surface contour that is an inverse of the surface contour of the defective surface of the substrate such as substrate 20 so as to provide a substantially conformal fit to the defective surface of the substrate.

According to one embodiment of the present invention, holding surface 42 has a surface contour that is an inverse of the surface contour of first side 22 of substrate 20 so as to provide a substantially conformal fit to first side 22 of substrate 20. For substrate 20 shown in FIG. 1 and substrate holder 40 shown in FIG. 3, first side 22 of substrate 20 is concave and holding surface 42 of substrate holder 40 has been made convex so that the concave first side 22 of substrate 20 forms a substantially conformal fit to concave holding surface 42 of substrate holder 40. Optionally, first side of substrate 20 may have a shape other than concave and/or other defects; for such substrates, holding surface 42 of substrate holder 40 is made with an appropriate opposite surface contour so that surface 22 and holding surface 42 form a substantially conformal fit when placed together.

In general, this means that for areas on the first side of the substrate that are concave, there are areas on the holding surface of the wafer holder that are convex so that the concave areas and the convex areas substantially fit together. For areas on the first side of the substrate that form a bump there is a corresponding area on the holding surface of the wafer holder that is recessed or indented so that the bump and the recessed area substantially fit together. For other types of features on the first side of the substrate, there are corresponding negative features formed on the holding surface so that the first side of the substrate and the holding surface of the wafer holder substantially fit together.

One of the results of having the substrate holder configured to provide a substantially conformal support for the defective side of a substrate is that deforming forces which can cause stresses such as flexural stress, bending stress, and/or torsional stress can be reduced, minimized, and/or eliminated. This means that the application of forces such as those caused by chucking mechanisms and/or forces of grinding processes do not add stress to the substrate because the substrate is supported at substantially every point and forces applied to the substrate occur only as substantially pure compression. The substantially pure compression forces that result from using the substrate holder do not produce residual stresses in the wafers fabricated by grinding the substrate. In contrast, fabricating wafers using grinding processes in which the substrate is subjected to such stress such as flexural stress result in residual stresses in the fabricated wafer.

According to one or more embodiments of the present invention, the substrate holder has a bottom surface configured for attachment to or support on a grinding machine. Optionally, this may mean that the bottom surface is flat and is used to contact a flat grinding machine support service. Optionally, the grinding machine support surface may comprise a chucking mechanism such as a mechanical chuck, an electrostatic chuck, and/or a vacuum chuck.

Optionally, the grinding machine support may have a variety of configurations. For such configurations, the bottom surface of the substrate holder may be configured suitably for attachment to the grinding machine support.

A variety of materials of construction can be used for the substrate holder. According to one embodiment of the present invention, the holding surface is substantially incompressible. According to one embodiment of the present invention, the hardness of the material of the holding surface is less than or equal to the hardness of the substrate. According to one embodiment of the present invention, the substrate holder comprises silicon. Optionally, the substrate holder may be fabricated from silicon. As another option, wafer holders according to one or more embodiments of the present invention are made of aluminum. According to one or more other embodiments of the present invention, the wafer holder comprises a holding surface formed by a layer of deposited material. Example configurations for wafer holders according to one or more embodiments of the present invention include, but are not limited to, aluminum oxide deposited on aluminum, titanium deposited on aluminum.

In the foregoing specification, the invention has been described with reference to specific embodiments; however, one of ordinary skill in the art appreciates that various modifications and changes can be made without departing from the scope of the present invention as set forth in the claims below. Accordingly, the specification is to be regarded in an illustrative, rather than a restrictive sense, and all such modifications are intended to be included within the scope of the present invention.

Benefits, other advantages, and solutions to problems have been described above with regard to specific embodiments; however, the benefits, advantages, solutions to problems, and any element(s) that may cause any benefit, advantage, or solution to occur or become more pronounced are not to be construed as a critical, required, or essential feature or element of any or all the claims.

As used herein, the terms “comprises,” “comprising,” “includes,” “including,” “has,” “having,” “at least one of,” or any other variation thereof, are intended to cover a non-exclusive inclusion. For example, a process, method, article, or apparatus that comprises a list of elements is not necessarily limited only to those elements, but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

What is claimed is:

1. A method of processing a defective substrate into a wafer, the method comprising:
grinding a second side of the substrate to flatness while supporting the substrate in a grinding apparatus so that there is minimum or substantially zero stress on the substrate; and
grinding a first side of the substrate to flatness while supporting the substrate in a grinding apparatus so that there is minimum or substantially zero stress on the substrate.

2. The method of claim 1, wherein the substrate is a hard material.

3. The method of claim 1, wherein the substrate comprises aluminum nitride.

4. The method of claim 1, wherein the substrate comprises aluminum carbide, aluminum oxide, boron nitride, cerium oxide, garnet, magnesium oxide, silicon carbide, silicon nitride, zirconium oxide, or combinations thereof.

5. The method of claim 1, wherein the grinding the second side of the substrate comprises:
providing a substantially rigid substrate holder having a holding surface, the holding surface having a surface contour opposite the surface contour of the first side of the substrate so as to provide a substantially conformal fit to the first side of the substrate; and
releasably binding the first side of the substrate to the holding surface of the substrate holder.

6. The method of claim 1,
wherein the grinding the second side comprises:
providing a substantially rigid substrate holder having a holding surface, the holding surface having a surface contour opposite the surface contour of the first side of the substrate so as to provide a substantially conformal fit to the first side of the substrate; and
releasably binding the first side of the substrate to the holding surface of the substrate holder; and
wherein the grinding the first side comprises:
holding the second side of the substrate ground to flatness.

7. A method of making a wafer, the method comprising:
providing a substrate having a first side and a second side, the first side having one or more defects;
providing a substantially rigid substrate holder having a holding surface, the holding surface having a surface contour that is an inverse of the surface contour of the first side of the substrate so as to provide a substantially conformal fit to the first side of the substrate;
releasably binding the first side of the substrate to the holding surface of the substrate holder; and
grinding the second side to produce a substantially flat surface while the substrate is bound to the substrate holder.

8. The method of claim 7, wherein the substrate is a hard material.

9. The method of claim 7, wherein the substrate comprises aluminum nitride.

10. The method of claim 7, wherein the substrate comprises aluminum carbide, aluminum oxide, boron nitride, cerium oxide, garnet, magnesium oxide, silicon carbide, silicon nitride, zirconium oxide, or combinations thereof.

11. The method of claim 7, wherein the releasably binding the first side of the substrate to the holding surface of the substrate holder is accomplished using an adhesive.

12. The method of claim 7, wherein the releasably binding the first side of the substrate to the holding surface of the substrate holder is accomplished using wax.

13. The method of claim 7, further comprising grinding the first side of the substrate to produce a substantially flat surface to produce the wafer.

14. The method of claim 7, wherein the wafer has bowing less than or equal to 10 micrometers, warpage less than or equal 10 micrometers, and/or total thickness variation less than or equal to 1 micrometer.

15. The method of claim 7, wherein the hardness of the substrate is greater than or equal to the hardness of the substrate holder.

16. The method of claim 7, wherein the substrate is aluminum nitride and the substrate holder is silicon.

17. The method of claim 7, wherein the substrate holder is silicon.

18. A method of making a wafer having a selected amount of stress, the method comprising:
providing a substrate having a first side and a second side;
providing a substantially rigid substrate holder having a holding surface, the holding surface having a surface contour that has a predetermined deviation from an inverse of the surface contour of the first side of the substrate so as to provide a partially conformal fit to the first side of the substrate;
releasably binding the first side of the substrate to the holding surface of the substrate holder; and
grinding the second side to produce a substantially flat surface while the substrate is bound to the substrate holder.

19. The method of claim 18, wherein the substrate is a hard material.

20. The method of claim 18, wherein the substrate comprises aluminum nitride.

21. The method of claim 18, wherein the substrate comprises aluminum carbide, aluminum oxide, boron nitride, cerium oxide, garnet, magnesium oxide, silicon carbide, silicon nitride, zirconium oxide, or combinations thereof.

22. The method of claim 18, further comprising separating the substrate from the substrate holder and grinding the first side of the substrate.

23. A substrate holder for a substrate having a defective surface, the substrate holder comprising a substantially rigid body having a holding surface, the holding surface having a surface contour that is an inverse of the surface contour of the defective surface of the substrate so as to provide a substantially conformal fit to the defective surface of the substrate.

24. The substrate holder of claim 23, wherein the substrate holder has a bottom surface configured for attachment to or for support on a grinding machine.

25. The substrate holder of claim 23, wherein the substrate holder comprises silicon.

26. The substrate holder of claim 23, wherein the substrate holder comprises aluminum.

27. The substrate holder of claim 23, wherein the holding surface comprises a deposited layer.

28. The substrate holder of claim 23, wherein the holding surface comprises an aluminum oxide layer deposited on aluminum.

29. The substrate holder of claim 23, wherein the holding surface comprises a titanium layer deposited on aluminum.

30. The substrate holder of claim 23, wherein the holding surface is substantially incompressible.

31. The substrate holder of claim 23, wherein the hardness of the material of the holding surface is less than or equal to the hardness of the substrate.
